(19) United States
(12) Patent Application Publication
(10) Pub. No.: US 2025/0062260 A1
(43) Pub. Date: Feb. 20, 2025

(54) SEMICONDUCTOR PACKAGE AND MANUFACTURING METHOD FOR THE SAME

(71) Applicant: SAMSUNG ELECTRONICS CO., LTD,, SUWON-SI (KR)

(72) Inventors: CHOONGBIN YIM, SUWON-SI (KR); JONGKOOK KIM, SUWON-SI (KR); Chengtar Wu, SUWON-SI (KR)

(21) Appl. No.: 18/608,838

(22) Filed: Mar. 18, 2024

(30) Foreign Application Priority Data
Aug. 17, 2023 (KR) 10-2023-0107503

(51) Int. Cl. H01L 23/00; H01L 23/31; H01L 25/00; H01L 25/16

(52) U.S. Cl. CPC H01L 24/08; H01L 23/3128; H01L 24/16; H01L 24/80; H01L 25/16; H01L 25/50; H01L 2224/08145; H01L 2224/16145; H01L 2224/16227; H01L 2224/80895; H01L 2924/181; H01L 2924/19011; H01L 2924/19041; H01L 2924/19104

(57) ABSTRACT

A semiconductor package includes: a substrate; a first semiconductor chip disposed on the substrate; a second semiconductor chip disposed on the first semiconductor chip; a passive component disposed on the first semiconductor chip; and an encapsulant that encapsulates the second semiconductor chip and the passive component. The first semiconductor chip includes a first through via that extends through at least a portion of the first semiconductor chip, and a first pad disposed on a first surface thereof and connected to the first through via. The passive component includes at least one trench and a second pad disposed on a first surface thereof and connected to the trench. The first pad and the second pad are directly bonded by contacting each other.

### CROSS-REFERENCE TO RELATED APPLICATION

This application claims priority under 35 U.S.C. 119 from Korean Patent Application No. 10-2023-0107503, filed in the Korean Intellectual Property Office on Aug. 17, 2023, the contents of which are incorporated herein by reference in their entirety.

### TECHNICAL FIELD

Embodiments of the present disclosure are directed to a semiconductor device and a fabricating method thereof.

### DISCUSSION OF THE RELATED ART

In the field of semiconductor package technology, various structures for three-dimensional integrated circuit (3D IC) semiconductor packages are being studied to perform packaging by stacking a lower semiconductor chip and an upper semiconductor chip in a vertical direction and connecting them with a through silicon via (TSV).

For example, there are cases where a passive component such as a capacitor that is electrically connected to a semiconductor chip is additionally positioned to improve performance, such as a power characteristic of the semiconductor chip. For example, a passive component is mounted side by side with the lower semiconductor chip on a package board, or a passive component is mounted along with solder balls on a lower surface of a main board on which the package board is mounted by using surface mount technology (SMT).

In the above-described structure, the passive component has a long electrical connection path with the semiconductor chip, so there is a limit to improving the performance of the semiconductor chip. In addition, a fine pitch might not be implemented when connecting the passive component to the main board or package board.

### SUMMARY

An embodiment of the present disclosure provides a semiconductor package and a manufacturing method therefor that includes a passive component with a short electrical connection path with a semiconductor chip.

Another embodiment of the present disclosure provides a semiconductor package and a manufacturing method therefor that includes a passive component that is connected with a semiconductor chip at a fine pitch.

An embodiment of the present disclosure provides a semiconductor package that includes: a substrate; a first semiconductor chip disposed on the substrate; a second semiconductor chip disposed on the first semiconductor chip; a passive component disposed on the first semiconductor chip; and an encapsulant that encapsulates the second semiconductor chip and the passive component. The first semiconductor chip includes a first through via that extends through at least a portion of the first semiconductor chip, and a first pad disposed on a first surface thereof and connected to the first through via. The passive component includes at least one trench and a second pad disposed on a first surface thereof and connected to the trench. The first pad and the second pad are directly bonded by contacting each other.

Another embodiment of the present disclosure provides a semiconductor package that includes: a substrate; a first semiconductor chip disposed on the substrate; a second semiconductor chip disposed on the first semiconductor chip; a passive component disposed side by side with the second semiconductor chip on the first semiconductor chip; and an encapsulant that encapsulates the second semiconductor chip and the passive component. The first semiconductor chip includes a first through via that extends through at least a portion of the first semiconductor chip and electrically connects the passive component and the first semiconductor chip; a first pad disposed on a first surface thereof and connected to the first through via, a second through via that extends through at least a portion of the first semiconductor chip and electrically connects the second semiconductor chip to the first semiconductor chip; a second pad disposed on the first surface and connected to the second through via, and a first insulating layer disposed on the first surface adjacent to a side surface of each of the first pad and the second pad. The passive component includes a third pad disposed on a first surface thereof and a second insulating layer disposed on the first surface adjacent to a side surface of the third pad. The first pad and the third pad are directly bonded by contacting each other.

Another embodiment of the present disclosure provides a manufacturing method for a semiconductor package that includes: attaching a first semiconductor chip to a substrate; attaching a second semiconductor chip and a passive component to the first semiconductor chip; and encapsulating the second semiconductor chip and the passive component by using an encapsulant. The positioning of the passive component on the first semiconductor is performed by hybrid bonding.

### BRIEF DESCRIPTION OF THE DRAWINGS

FIG. 1 is a schematic cross-sectional view of a semiconductor package according to an embodiment of the present disclosure.

FIG. 2 is a schematic cross-sectional view of a semiconductor package according to an embodiment of the present disclosure.

FIG. 3 is a schematic cross-sectional view of a semiconductor package according to an embodiment of the present disclosure.

FIG. 4 is a schematic cross-sectional view of a semiconductor package according to an embodiment of the present disclosure.

FIG. 5A to FIG. 5E schematically illustrate a manufacturing process of a semiconductor package according to an exemplary embodiment of the present disclosure.

FIG. 6A to FIG. 6F illustrate a schematic manufacturing process of a semiconductor package according to an exemplary embodiment of the present disclosure.

### DETAILED DESCRIPTION

Embodiments of the present disclosure will be described more fully hereinafter with reference to the accompanying drawings, in which embodiments of the disclosure are shown. As those skilled in the art would realize, the described embodiments may be modified in various different ways, all without departing from the spirit or scope of the present disclosure.

Like numerals may refer to like or similar constituent elements throughout the specification.

It will be understood that when an element such as a layer, film, region, or substrate is referred to as being “on” another element, it can be directly on the other element or intervening elements may also be present.

In addition, throughout this specification and the claims that follow, when it is described that an element is “coupled/connected” to another element, the element may be “directly coupled/connected” to the other element or “indirectly coupled/connected” to the other element through a third element. In a similar sense, this includes being “physically connected” as well as being “electrically connected

Hereinafter, a semiconductor package according to embodiments of the present disclosure will be described with reference to the drawings.

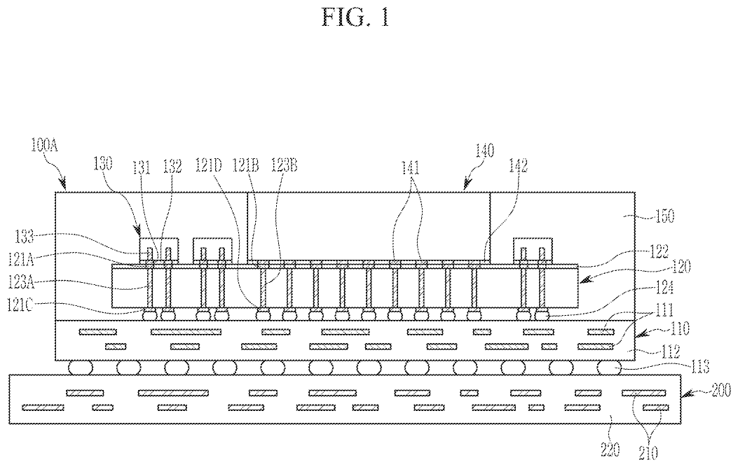

Referring to FIG. 1, in an embodiment, a semiconductor package 100A includes a substrate 110, a first semiconductor chip 120 disposed on the substrate 110, a passive component 130 disposed on the first semiconductor chip 120, a second semiconductor chip 140 disposed on the first semiconductor chip 120, and an encapsulant 150 that encapsulates the second semiconductor chip 140 and the passive component 130.

In addition, the semiconductor package 100A is mounted on another substrate 200 separate from the semiconductor package 100A.

The substrate 110 electrically connects the semiconductor package 100A to the substrate 200. The substrate 110 includes known substrate components, such as a wiring layer 111 and an insulating layer 112. A type of substrate 110 is not particularly limited, and various types of substrates used in a semiconductor package can be used without limitation.

In addition, the substrate 110 is connected to the substrate 200 through a conductive bump 113. The conductive bump 113 is disposed between the substrate 110 and the substrate 200 to connect them to each other. In an embodiment, the conductive bump 113 is a solder ball, but embodiments of the present disclosure are not necessarily limited thereto.

The first semiconductor chip 120 is disposed on the substrate 110 and connected to the substrate 110.

The first semiconductor chip 120 includes a first pad 121A and a second pad 121B disposed on a first surface thereof, an insulating layer 122 disposed on the first surface, a third pad 121C and a fourth pad 121D disposed on a second surface thereof that is opposite to the first surface, and a first through via 123A and a second through via 123B that at least extend through the insulating layer 122 and the first semiconductor chip 120 disposed on the first surface. In some embodiments, first semiconductor chip 120 does not include some of the above-described configurations.

The first pad 121A connects the passive component 130 and the first semiconductor chip 120. The first pad 121A is disposed on the first surface of the first semiconductor chip 120 and is connected to the first through via 123A, and the passive component 130 is electrically connected to the first semiconductor chip 120 through the first pad 121A and the first through via 123A.

The passive component 130 includes a pad 131 formed on a surface that faces the first surface of the first semiconductor chip 120, and an insulating layer 132 is disposed on the side surface of the pad 131. The first pad 121A and the pad 131 of the passive component 130 are hybrid bonded. For example, the first pad 121A and the pad 131 of the passive component 130 are directly bonded by contacting each other.

The second pad 121B connects the second semiconductor chip 140 and the first semiconductor chip 120. The second pad 121B is spaced apart from the first pad 121A on the first surface of the first semiconductor chip 120 and is connected to the second through via 123B, and the second semiconductor chip 140 is electrically connected to the first semiconductor chip 120 through the second pad 121B and the second through via 123B.

The second semiconductor chip 140 includes a pad 141 formed on a surface that faces the first surface of the first semiconductor chip 120, and an insulating layer 142 is disposed on the side surface of the pad 141. The second pad 121B and the pad 141 of the second semiconductor chip 140 are also hybrid bonded. For example, the second pad 121B and the pad 141 of the second semiconductor chip 140 are directly bonded by contacting each other.

The first pad 121A and the second pad 121B are disposed at the same level. The first pad 121A and the second pad 121B are formed through a same process to be disposed at the same level. In addition, as described below, the insulating layer 122 is disposed adjacent to side surfaces of the first pad 121A and/or the second pad 121B, and it may be desirable for disposition of the insulating layer 122 for the first pad 121A and the second pad 121B to be disposed at the same level.

The third pad 121C connects the first semiconductor chip 120 and the substrate 110. The third pad 121C is disposed on the second surface of the first semiconductor chip 120 and is connected to the first through via 123A, and the passive component 130 connected to the first through via 123A is also electrically connected to the substrate 110. Accordingly, the passive component 130 is electrically connected to the second semiconductor chip 140 through the first semiconductor chip 120 and the substrate 110, thereby increasing performance of the second semiconductor chip 140.

However, in some embodiments, the first semiconductor chip 120 does not include the third pad 121C. For example, the passive component 130 is connected to the first semiconductor chip 120 to increase the performance of the first semiconductor chip 120, but is not connected to the second semiconductor chip 140. For example, the connection between the passive component 130 and the substrate 110 is not necessary, and the third pad 121C that connects the first through via 123A and the substrate 110 is not necessary.

The fourth pad 121D also connects the first semiconductor chip 120 and the substrate 110. The second pad 121B is disposed on the second surface of the first semiconductor chip 120 and is connected to the second through via 123B, and the second semiconductor chip 140 connected to the second through via 123B is also electrically connected to the substrate 110.

Materials for each of the first pad 121A, the second pad 121B, the third pad 121C, and the fourth pad 121D, includes one or more of aluminum (Al), copper (Cu), gold (Au), silver (Ag), platinum (Pt), or palladium (Pd), etc.

A number of each of the first pad 121A, the second pad 121B, the third pad 121C, and the fourth pad 121D is not particularly limited, and in other embodiments can vary from what is shown in the drawing.

In addition, the first semiconductor chip 120 may further include an additional pad on the second surface of the first semiconductor chip 120 that is not connected to the through vias 123A and 123B. The additional pad electrically connects the first semiconductor chip 120 and the substrate 110.

The insulating layer 122 is disposed on the first surface of the first semiconductor chip 120 adjacent to a side surface of the first pad 121A. In addition, the insulating layer 122 is disposed adjacent to a side surface of the second pad 121B.

When the first semiconductor chip 120 and the passive component 130 are connected through hybrid bonding, the insulating layer 122 disposed on the side surface of the first pad 121A is bonded by directly contacting the insulating layer 132 disposed on the side surface of the pad 131 of the passive component 130. However, a gap can form between the two insulating layers 122 and 132, depending on the materials and processes used to from the insulating layer 122 of the first semiconductor chip 120 and the insulating layer 132 of the passive component 130.

Similarly, when the first semiconductor chip 120 and the second semiconductor chip 140 are connected by hybrid bonding, the insulating layer 122 disposed on the side surface of the second pad 121B is bonded by directly contacting the insulating layer 142 disposed on the side surface of the pad 141 of the second semiconductor chip 140. However, a gap can form between the two insulating layers 122 and 142, depending on the materials and processes used to form the insulating layer 122 of the first semiconductor chip 120 and the insulating layer 142 of the second semiconductor chip 140.

An insulating material is used as a material for the insulating layer 122, such as at least one of a silicon oxide, a silicon nitride, or a polymer such as polyimide or benzocyclobutene (BCB).

The first through via 123A extends through at least a portion of the first semiconductor chip 120 and electrically connects the passive component 130 and the first semiconductor chip 120 together with the first pad 121A. The first through via 123A is connected to the passive component 130 so that the passive component 130 increases performance of the first semiconductor chip 120.

The second through via 123B extends through at least a portion of the first semiconductor chip 120 and electrically connects the second semiconductor chip 140 and the first semiconductor chip 120 together with the second pad 121B. In addition, the second through via 123B provides an electrical connection path between the second semiconductor chip 120 and the substrate 110.

The drawing shows the first through via 123A and the second through via 123B as extending through the entire first semiconductor chip 120, but in some embodiments, the first through via 123A and the second through via 123B extend through only a portion of the first semiconductor chip 120. For example, the first through via 123A and the second through via 123B are connected to the pads 121A, 121B, 121C, and 121D through an internal circuit of the first semiconductor chip 120.

A via-first, a via-middle or a via-last method may be used without limitation to form each of the first through via 123A and the second through via 123B. In addition, one of a PVD process, a CVD process, a plating process, etc. can be used to form the first through via 123A and the second through via 123B.

A conductive material is a material for the first through via 123A and the second through via 123B, and includes, for example, at least one of tungsten (W), copper (Cu), aluminum (Al), or doped poly silicon, etc.

A type of the first semiconductor chip 120 is not particularly limited, and can be one of various types of chips, such as a logic chip such as a central processing unit (CPU), a graphics processing unit (GPU), or an application processor (AP), or a memory chip such as a dynamic RAM (DRAM), a static RAM (SRAM), or a flash memory.

A width of the first semiconductor chip 120 is greater than a width of each of the second semiconductor chip 140 and the passive component 130 to position the second semiconductor chip 140 and the passive component 130 on the first semiconductor chip 120. The width refers to a dimension in a direction parallel to an extension direction of the first or second surface of the first semiconductor chip 120 and perpendicular to a thickness direction of the first semiconductor chip 120.

The first semiconductor chip 120 is connected to the substrate 100 through a conductive bump 124. The conductive bump 124 is disposed between the substrate 110 and the first semiconductor chip 120 and connects them to each other. In an embodiment, the conductive bump 124 is a solder ball, but embodiments of the present disclosure are not necessarily limited thereto.

The passive component 130 is disposed side by side with the second semiconductor chip 140 on the first semiconductor chip 120.

The passive component 130 is connected to the first semiconductor chip 120 to increase performance of the first semiconductor chip 120, and, if necessary, is connected to the second semiconductor chip 140 to increase the performance of the second semiconductor chip 120. For example, the passive component 130 is connected to the first semiconductor chip 120 through the first through via 123A to increase the performance of the first semiconductor chip 120. For another example, the passive component 130 is connected to the second semiconductor chip 140 through the first through via 123A, the substrate 110, and the second through via 123B to increase the performance of the second semiconductor chip 120. In other embodiments, the passive component 130 is connected to the second semiconductor chip 140 through the first through via 123A, the internal circuit of the first semiconductor chip 120, and the second through via 123A without going through the substrate 110, thereby increasing the performance of the first semiconductor chip 120.

The passive component 130 includes the pad 131 disposed on a first surface of the passive component 130, the insulating layer 132 disposed on the first surface, and at least one trench 133.

The pad 131 is connected to the trench 133 and connects the passive component 130 to the first semiconductor chip 120. For example, the pad 131 is connected to the first pad 121A of the first semiconductor chip 120, thereby connecting the passive component 130 to the first semiconductor chip 120. For example, the pad 131 is bonded by directly contacting the first pad 121A of the first semiconductor chip 120.

Materials for the pad 131 include at least one of aluminum (Al), copper (Cu), gold (Au), silver (Ag), platinum (Pt), or palladium (Pd), etc.

The insulating layer 132 is disposed adjacent to a side surface of the pad 131. As described above, the insulating layer 132 is bonded by directly contacting the insulating layer 122 of the first semiconductor chip 120.

An insulating material used for the insulating layer 132, includes, e.g., at least one of a silicon oxide, a silicon nitride, or a polymer such as polyimide or benzocyclobutene (BCB).

The passive component 130 may be an integrated stacked capacitor (ISC) that includes a trench 133. The trench 133 includes a plurality of metal layers that store charges and an insulating layer disposed between the metal layers. When the passive component 130 is an integrated stacked capacitor, the passive component 130 not only has excellent capacity, performance, and high reliability, but can also provide design flexibility. In addition, the passive component 130 provides a structure advantageous for hybrid bonding with the first semiconductor chip 120.

A number of passive components 130 is not particularly limited, and, in other embodiments, can vary from that shown in the drawing.

The second semiconductor chip 140 includes the pad 141 disposed on a first surface thereof and the insulating layer 142 disposed on the first surface.

The pad 141 connects the second semiconductor chip 140 to the first semiconductor chip 120. For example, the pad 141 is connected to the second pad 121B of the first semiconductor chip 120, thereby connecting the second semiconductor chip 140 to the first semiconductor chip 120. For example, the pad 141 is bonded by directly contacting the second pad 121B of the first semiconductor chip 120.

Materials for the pad 141 include at least one of aluminum (Al), copper (Cu), gold (Au), silver (Ag), platinum (Pt), or palladium (Pd), etc.

The insulating layer 142 disposed adjacent to a side surface of the pad 141. As described above, the insulating layer 142 is bonded by directly contacting the insulating layer 122 of the first semiconductor chip 120.

An insulating material for the insulating layer 142, includes, e.g., at least one of a silicon oxide, a silicon nitride, or a polymer such as polyimide or benzocyclobutene (BCB).

As illustrated in the figure, the insulating layer 132 and the insulating layer 142 are spaced apart from each other in a horizontal direction, such as a direction parallel to an extension direction of the first surface of the first semiconductor chip 120.

A type of the second semiconductor chip 140 is not particularly limited, and in some embodiments is a memory chip such as a dynamic RAM (DRAM), a static RAM (SRAM), or a flash memory. However, embodiments of the present disclosure are not necessarily limited thereto, and in other embodiment, the second semiconductor chip 140 is a logic chip such as a central processing unit (CPU), a graphics processing unit (GPU), an application processor (AP), or an analog chip.

The encapsulant 150 encapsulates the second semiconductor chip 140 and the passive component 130, and further encapsulates the first semiconductor chip 120. A width of the encapsulant 150 is the same as that of the substrate 110.

A top surface of the second semiconductor chip 140 that is parallel to the first surface of the first semiconductor chip 120 is exposed by the encapsulant 150. Through the above-described structure, heat dissipation of the semiconductor package 100A is increased. However, if necessary, in some embodiments, the top surface of the second semiconductor chip 140 is covered with the encapsulant 150, and is not exposed by the first surface of the encapsulant 150.

The encapsulant 150 is formed of a thermosetting resin such as one of an epoxy resin, an epoxy molding compound (EMC), or the like. A process of molding the encapsulant 150 includes at least one of compression molding, transfer molding, etc.

The substrate 200 on which the semiconductor package 100A is disposed includes substrate components such as a wiring layer 210 and an insulation layer 220. A type of the substrate 200 is not particularly limited, and various types of substrates, such as a main board, can be used without limitation.

However, a 3D integrated circuit semiconductor package may include cases where a passive component such as a capacitor that is electrically connected to a semiconductor chip is additionally disposed to increase performance such as power characteristics of the semiconductor chip. For example, a passive component is mounted side by side with the lower semiconductor chip on a package board, or a passive component is mounted along with solder balls on a lower surface of a main board on which the package board is mounted by using surface mount technology (SMT).

In an above-described structure, the passive component has a long electrical connection path with the semiconductor chip, so there is a limit to increasing the performance of the semiconductor chip. In addition, a fine pitch might not be implemented when connecting the passive component to the main board or package board.

However, in the semiconductor package 100A according to an exemplary embodiment, the passive component 130 is connected by hybrid bonding on the first semiconductor chip 120 rather than on the substrates 110 and 200, and thus the passive component 130 has a short electrical connection path with the first semiconductor chip 120. In addition, the passive component 130 is connected to the first semiconductor chip 120 at a fine pitch.

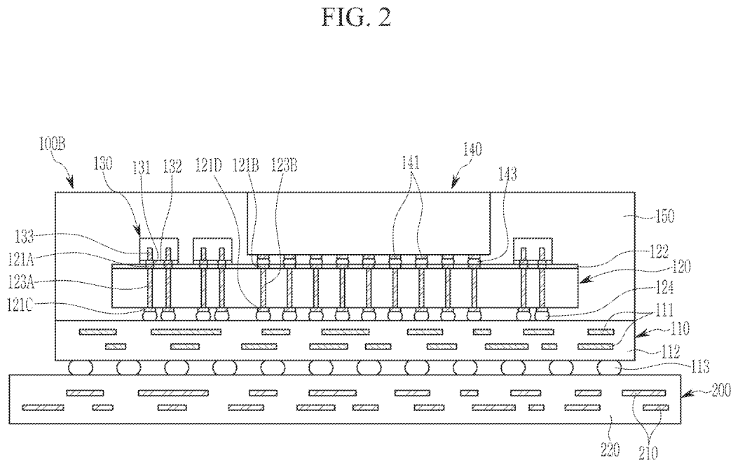

Referring to FIG. 2, a semiconductor package 100B according to an exemplary embodiment uses a connection method of the second semiconductor chip 140 and the first semiconductor chip 120 that differs from that of the semiconductor package 100A shown in FIG. 1.

Referring to the drawing, the second semiconductor chip 140 further includes a conductive bump 143 disposed on the pad 141. The second pad 121B of the first semiconductor chip 120 and the pad 141 of the second semiconductor chip 140 are connected to the conductive bump 143.

In addition, the second semiconductor chip 140 does not include the insulating layer 142. Since the second semiconductor chip 140 and the first semiconductor chip 120 are not connected through hybrid bonding, the insulating layer 142 is not needed.

A description of other components is substantially the same as that described for the semiconductor package 100A according to an embodiment of the present disclosure, and thus a repeated detailed description of these components is omitted.

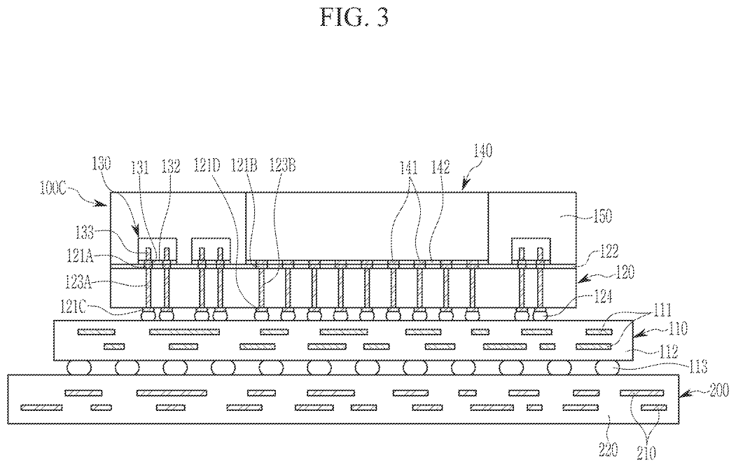

Referring to FIG. 3, in an embodiment, the encapsulant 150 of the semiconductor package 100C is disposed on the first semiconductor chip 120 and encapsulates the second semiconductor chip 140 and the passive component 130. In addition, the encapsulant 150 covers at least a portion of the first surface of the first semiconductor chip 120, but does not cover the side surface. A width of the encapsulant 150 is the same as that of the first semiconductor chip 120.

A description of other components is substantially the same as that described for the semiconductor package 100A according to an embodiment of the present disclosure, and thus a repeated detailed description of these components is omitted.

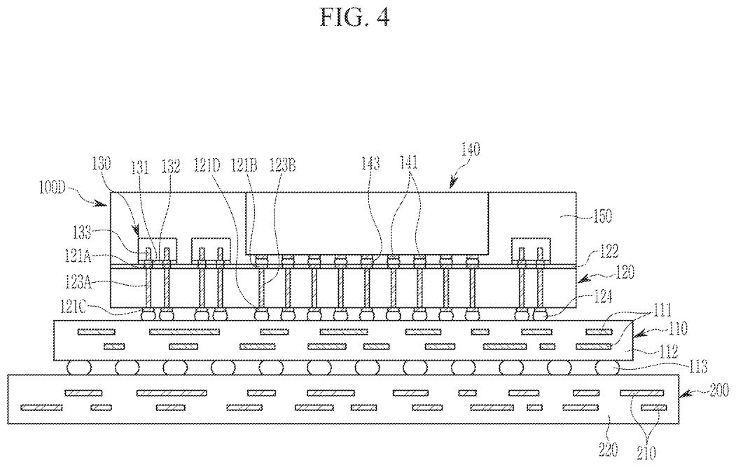

Referring to FIG. 4, a semiconductor package 100D according to another exemplary embodiment, a connection method of the second semiconductor chip 140 and the first semiconductor chip 120 differs from that of the semiconductor package 100C shown in FIG. 3.

Referring to the drawing, the second semiconductor chip 140 further includes a conductive bump 143 disposed on the pad 141. The second pad 121B of the first semiconductor chip 120 and the pad 141 of the second semiconductor chip 140 are connected to the conductive bump 143.

In addition, the second semiconductor chip 140 does not include the insulating layer 142. Since the second semiconductor chip 140 and the first semiconductor chip 120 are not connected through hybrid bonding, the insulating layer 142 is not needed.

Like the encapsulant 150 of the semiconductor package 100C, the encapsulant 150 of the semiconductor package 100D is disposed on the first semiconductor chip 120 and covers the second semiconductor chip 140 and the passive component 130. In addition, the encapsulant 150 covers at least a portion of a first surface of the first semiconductor chip 120, but does not cover the side surface. A width of the encapsulant 150 is the same as that of the first semiconductor chip 120.

A description of other components is substantially the same as those described in the description of the semiconductor package 100A according to an embodiment of the present disclosure, and thus a repeated detailed description of these components is omitted.

In addition, a semiconductor package manufacturing method according to an exemplary embodiment of the present disclosure includes positioning the first semiconductor chip 120 on the substrate 110, positioning the second semiconductor chip 140 and the passive component 130 on the first semiconductor chip 120, and encapsulating the second semiconductor chip 140 and the passive component 130 with the encapsulant 150. In addition, a semiconductor package manufacturing method according to an exemplary embodiment of the present disclosure further includes exposing a first surface of the second semiconductor chip 140 by grinding the encapsulant 150.

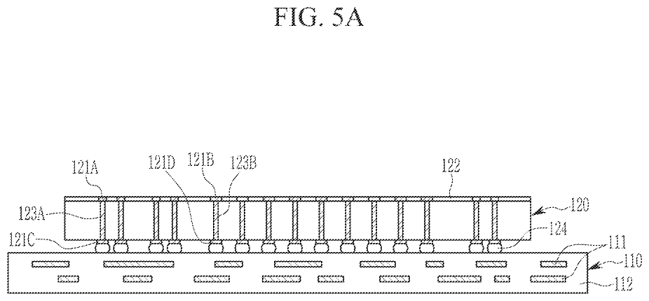

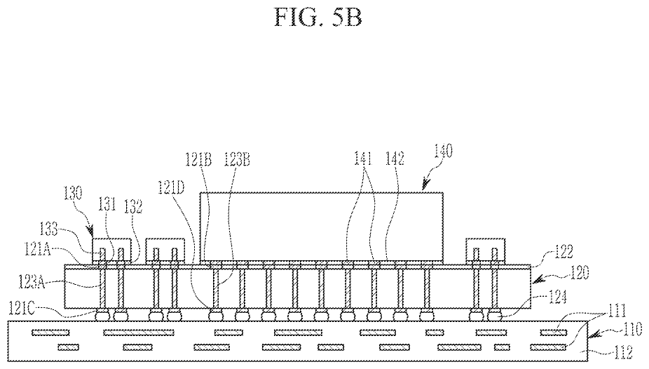

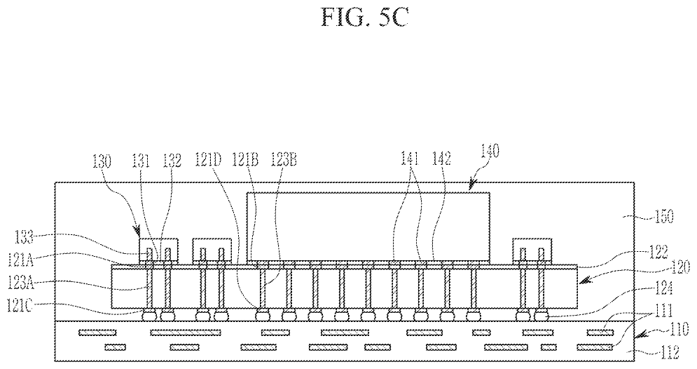

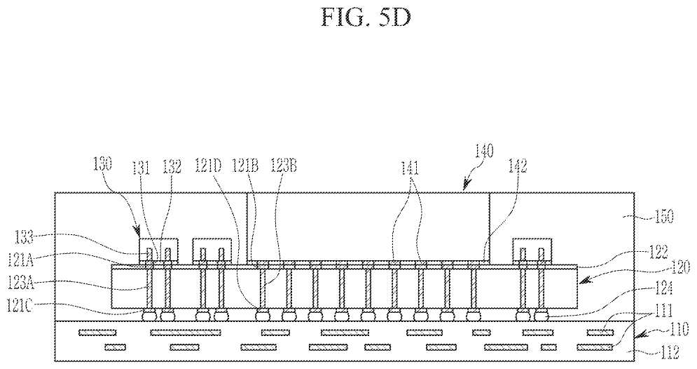

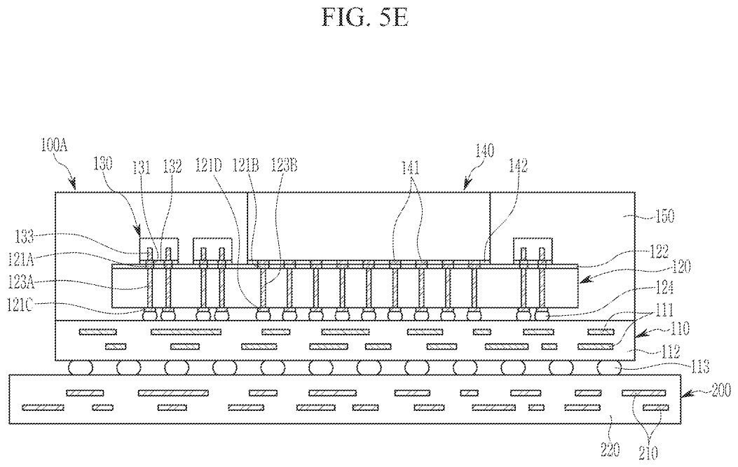

FIG. 5A to FIG. 5E schematically illustrate a manufacturing process of a semiconductor package according to an exemplary embodiment of the present disclosure.

Referring to FIG. 5A, in an embodiment, the first semiconductor chip 120 is disposed on the substrate 110. The first semiconductor chip 120 is connected to the substrate 110 by using the conductive bump 124.

Referring to FIG. 5B, in an embodiment, the second semiconductor chip 140 and the passive component 130 are disposed on the first semiconductor chip 120. The second semiconductor chip 140 and passive components 130 are attached onto the first semiconductor chip 120 by hybrid bonding. However, as illustrated in FIG. 2, the second semiconductor chip 140 may be attached onto the first semiconductor chip 120 by the conductive bump 143.

A disposition order of the second semiconductor chip 140 and the passive component 130 is not particularly limited. For example, the second semiconductor chip 140 can be attached first, and then the passive component 130 is attached, or the passive component 130 can be disposed first, and then the second semiconductor chip 140 is attached. In some embodiments, the second semiconductor chip 140 and the passive component 130 are attached together. When the second semiconductor chip 140 and the passive component 130 are attached together through hybrid bonding, a special type of jig that presses the second semiconductor chip 140 and the passive component 130 together is used.

Referring to FIG. 5C, in an embodiment, the first semiconductor chip 120, the second semiconductor chip 140, and the passive component 130 are encapsulated by the encapsulant 150. A process of encapsulating with the encapsulant 150 is performed by one of compression molding, transfer molding, etc.

Referring to FIG. 5D, in an embodiment, a first surface of the second semiconductor chip 140 is exposed by grinding the encapsulant 150. Accordingly, a heat dissipation characteristic of the semiconductor package is increased.

Referring to FIG. 5E, in an embodiment, the manufactured semiconductor package 100A is mounted on the substrate 200 using the conductive bump 113.

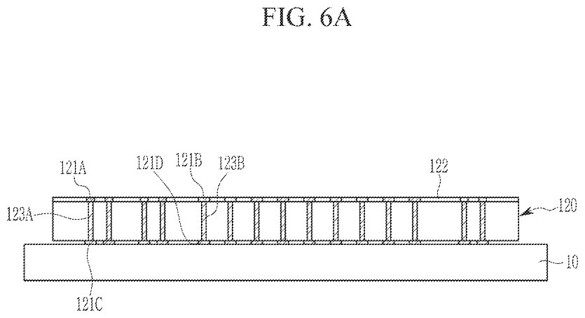

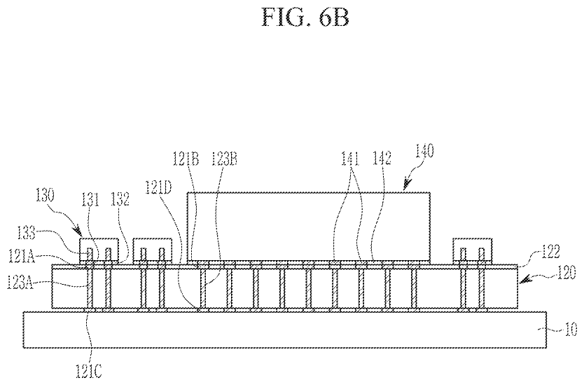

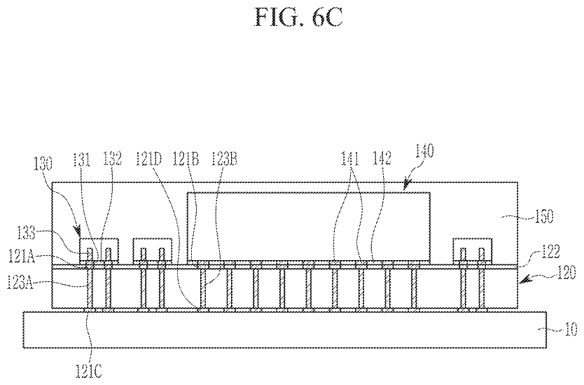

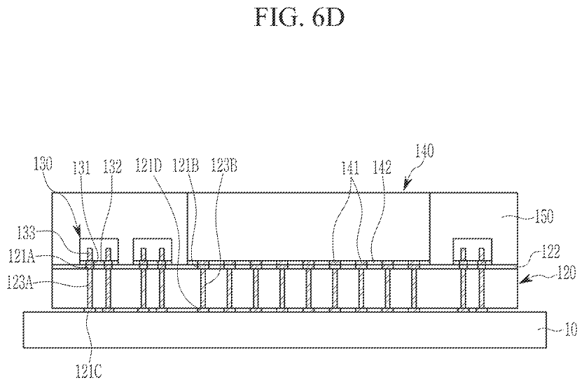

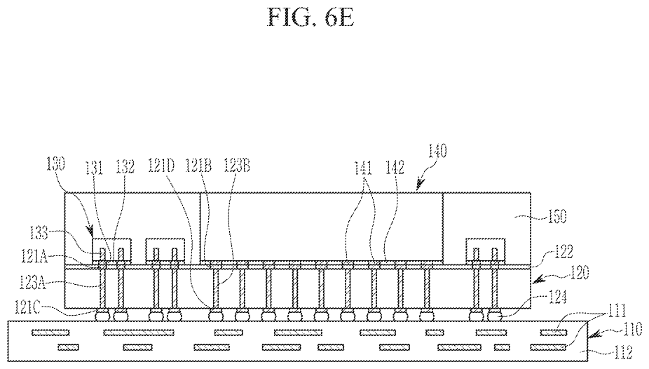

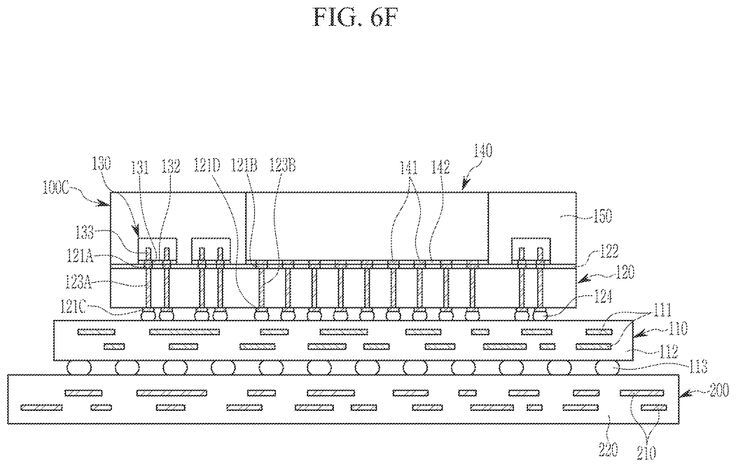

FIG. 6A to FIG. 6F illustrate a manufacturing process of a semiconductor package according to an exemplary embodiment of the present disclosure.

Referring to FIG. 6A to FIG. 6D, in a semiconductor package manufacturing method according to an exemplary embodiment, the first semiconductor chip 120 is attached to a carrier substrate 10, the second semiconductor chip 140 and the passive component 130 are attached to the first semiconductor chip 120, the second semiconductor chip 140 and the passive component 130 are encapsulated with the encapsulant 150, and the encapsulant 150 is ground to expose a first surface of the second semiconductor chip 140.

Referring to FIG. 6E, in an embodiment, the carrier substrate 10 is detached and the first semiconductor chip 120, which includes the second semiconductor chip 140 and the passive component 130 attached thereto, is attached to the substrate 110. For example, according to an exemplary embodiment, attaching the first semiconductor chip 120 to the substrate 110 is performed after attaching the second semiconductor chip 140 and the passive component 130 to the first semiconductor chip 120.

Referring to FIG. 6F, the manufactured semiconductor package 100C is attached to the substrate 200 by the conductive bump 113, like the semiconductor package 100A.

A description of other components is substantially the same as the description with respect to FIGS. 5A to 5E of a semiconductor package manufacturing method according to an exemplary embodiment of the present disclosure, and thus a repeated detailed description of these components is omitted.

While embodiments of this disclosure have been described in connection with accompanying drawings, it is to be understood that embodiments of the disclosure are not limited to disclosed embodiments, but, on the contrary, are intended to cover various modifications and equivalent dispositions included within the spirit and scope of the appended claims.

What is claimed is:

1. A semiconductor package, comprising:
a substrate;
a first semiconductor chip disposed on the substrate;
a second semiconductor chip disposed on the first semiconductor chip;
a passive component disposed on the first semiconductor chip; and
an encapsulant that encapsulates the second semiconductor chip and the passive component,
wherein the first semiconductor chip includes a first through via that extends through at least a portion of the first semiconductor chip, and a first pad disposed on a first surface thereof and connected to the first through via,
the passive component includes at least one trench and a second pad disposed on a first surface thereof and connected to the trench, and
the first pad and the second pad are directly bonded by contacting each other.

2. The semiconductor package of claim 1, wherein
the first semiconductor chip further includes a first insulating layer disposed on the first surface thereof and adjacent to a side surface of the first pad,
the passive component further includes a second insulating layer disposed on the first surface thereof and adjacent to a side surface of the second pad, and
the first insulating layer and the second insulating layer are directly bonded by contacting each other.

3. The semiconductor package of claim 2, wherein
the first semiconductor chip further includes a third pad disposed on the first surface thereof that is spaced apart from the first pad, and
the second semiconductor chip includes a fourth pad disposed on a first surface thereof and connected to the third pad.

4. The semiconductor package of claim 3, wherein
the third pad and the fourth pad are directly bonded by contacting each other.

5. The semiconductor package of claim 4, wherein
the first insulating layer is disposed adjacent to a side surface of the third pad as well,
the second semiconductor chip further includes a third insulating layer disposed on the first surface thereof and adjacent to a side surface of the fourth pad, and
the first insulating layer and the third insulating layer are directly bonded by contacting each other.

6. The semiconductor package of claim 5, wherein
the second insulating layer and the third insulating layer are spaced apart from each other.

7. The semiconductor package of claim 3, wherein
the second semiconductor chip further includes a conductive bump disposed on the fourth pad, and
the third pad and the fourth pad are connected by the conductive bump,

8. The semiconductor package of claim 1, wherein
the first semiconductor chip further includes a second through via that extends through at least a portion of the first semiconductor chip and electrically connects the second semiconductor chip to the first semiconductor chip.

9. The semiconductor package of claim 1, wherein
the encapsulant further encapsulates the first semiconductor chip.

10. The semiconductor package of claim 1, wherein
a first surface of the second semiconductor chip is exposed by the encapsulant.

11. The semiconductor package of claim 1, wherein
the passive component is an integrated stacked capacitor (ISC).

12. A semiconductor package, comprising:
a substrate;
a first semiconductor chip disposed on the substrate;
a second semiconductor chip disposed on the first semiconductor chip;
a passive component disposed side by side with the second semiconductor chip on the first semiconductor chip; and
an encapsulant that encapsulates the second semiconductor chip and the passive component,
wherein the first semiconductor chip includes
a first through via that extends through at least a portion of the first semiconductor chip and electrically connects the passive component and the first semiconductor chip,
a first pad disposed on a first surface thereof and connected to the first through via,
a second through via that extends through at least a portion of the first semiconductor chip and electrically connects the second semiconductor chip to the first semiconductor chip,
a second pad disposed on the first surface and connected to the second through via, and
a first insulating layer disposed on the first surface adjacent to a side surface of each of the first pad and the second pad,
wherein the passive component includes a third pad disposed on a first surface thereof and a second insulating layer disposed on the first surface adjacent to a side surface of the third pad, and
the first pad and the third pad are directly bonded by contacting each other.

13. The semiconductor package of claim 12, wherein
the second semiconductor chip includes a fourth pad disposed on a first surface thereof, and
the second pad and the fourth pad are directly bonded by contacting each other.

14. The semiconductor package of claim 12, wherein
the second semiconductor chip includes a fourth pad disposed on a first surface thereof and a conductive bump disposed on the fourth pad, and
the second pad and the fourth pad are connected by the conductive bump.

15. The semiconductor package of claim 12, wherein
the first pad and the second pad are disposed at the same level.

16. The semiconductor package of claim 12, wherein
the first insulating layer and the second insulating layer are directly bonded by contacting each other.

17. A manufacturing method for a semiconductor package, comprising:
attaching a first semiconductor chip to a substrate;
attaching a second semiconductor chip and a passive component to the first semiconductor chip; and
encapsulating the second semiconductor chip and the passive component by using an encapsulant,
wherein the passive component is attached to the first semiconductor chip by hybrid bonding.

18. The manufacturing method of claim 17, wherein
the second semiconductor chip is attached to the first semiconductor chip by hybrid bonding.

19. The manufacturing method of claim 17, wherein
the second semiconductor chip is attached to the first semiconductor chip with a conductive bump.

20. The preparing method of claim 17, further comprising:
grinding the encapsulant such that a first surface of the second semiconductor chip is exposed.
